(19) United States
(12) Patent Application Publication
(10) Pub. No.: US 2026/0312428 A1
(43) Pub. Date: Oct. 8, 2026

(54) FOLDABLE WIRELESS POWER BANK

(71) Applicant: SHENZHEN LIDIAN TECHNOLOGY CO., LTD, Shenzhen (CN)

(72) Inventor: Yangan DU, Changsha (CN)

(73) Assignee: SHENZHEN LIDIAN TECHNOLOGY CO.,LTD, Shenzhen (CN)

(21) Appl. No.: 19/330,471

(22) Filed: Sep. 16, 2025

(30) Foreign Application Priority Data
Apr. 8, 2025 (CN) 2025206476532

(51) Int. Cl. H02J 50/00; H05K 5/00; H05K 5/02; H05K 5/03

(52) U.S. Cl. CPC H02J 50/005; H05K 5/0086; H05K 5/0221; H05K 5/0226; H05K 5/0243; H05K 5/0247; H05K 5/03

(57) ABSTRACT

The present disclosure relates to a foldable wireless power bank. The foldable wireless power bank includes: a bottom cover; a main board, being fixedly mounted in the bottom cover, where the main board is connected to a battery; a bottom housing, being provided with magnet grooves, convex buckles and shaft holes, the convex buckles and the concave buckles match each other, and cover closing magnets are fixedly arranged in the magnet grooves formed at the bottom housing; and an opening and closing mechanism, being mounted at the shaft holes formed at the bottom housing, where a charging mechanism is mounted on the opening and closing mechanism, the charging mechanism is connected to a wire. The foldable wireless power bank can not only perform wireless charging, but also is convenient to fold. Moreover, the foldable wireless power bank has relatively large damping after folding due to attraction of the magnets.

### CROSS-REFERENCE TO RELATED APPLICATIONS

This application claims priority to Chinese Patent Application No. 2025206476532 filed on Apr. 8, 2025 and entitled “FOLDABLE WIRELESS POWER BANK”, which is incorporated herein by reference in its entirety.

### TECHNICAL FIELD

The present disclosure relates to the technical field of charging devices, and in particular to a foldable wireless power bank.

### BACKGROUND

Power bank, also known as portable charger, is a portable device that integrates power supply and charging functions, which is mainly used for providing power support for mobile devices such as mobile phones and tablet computers.

Although an existing wireless power bank can perform wireless charging, there are still some problems: firstly, the existing wireless power bank is usually inconvenient to fold, resulting inconvenient carrying; and secondly, since damping of the existing wireless power bank after folding is relatively small, the existing wireless power bank is easy to unfold outwards due to a slight external force. Therefore, a foldable wireless power bank is needed to solve the above problems.

### SUMMARY

An objective of the example of the present disclosure is to provide a foldable wireless power bank, so as to solve the following problems: the existing wireless power bank is inconvenient to fold, and damping after folding is relatively small.

The example of the present disclosure is implemented as follows: a foldable wireless power bank, including: a bottom cover, where the bottom cover is provided with a key hole and concave buckles on side surfaces, and the key hole formed at the bottom cover is fitted with a key cap; a main board, being fixedly mounted in the bottom cover through screws and tightly attached to the key cap, where the main board is connected to a battery mounted in the bottom cover; a bottom housing, being provided with magnet grooves, convex buckles and shaft holes, where the convex buckles are arranged on side surfaces of the bottom housing, the convex buckles and the concave buckles match each other, the bottom housing is clamped on the concave buckles arranged on the bottom cover through the convex buckles, and cover closing magnets are fixedly arranged in the magnet grooves formed at the bottom housing; and an opening and closing mechanism, being mounted at the shaft holes formed at the bottom housing, where the opening and closing mechanism is capable of rotating on the bottom housing so as to achieve opening and closing of the power bank, a charging mechanism is mounted on the opening and closing mechanism, the charging mechanism is connected to a wire, an end, farthest away from the charging mechanism, of the wire is connected to the main board, and the wire passes through the shaft holes.

Preferably, the opening and closing mechanism includes: a top housing, being provided with a fixing groove, where the top housing matches the shaft holes formed at the bottom housing, the charging mechanism is mounted on the fixing groove formed at the top housing, a damping tube is inserted into the top housing, a knurled shaft with larger and smaller edges is inserted into the top housing and the shaft holes formed at the bottom housing, and the knurled shaft with larger and smaller edges passes through the damping tube; and a top housing wire cover, being mounted on the top housing, where a rotating shaft wire cover is mounted on a rotating shaft of the top housing, and a left locking pin and a right locking pin used for blocking retreating space of the bottom housing are clamped into a left side and a right side of the bottom housing respectively.

Preferably, the charging mechanism includes: a charging ring, being mounted on the top housing and connected to the wire, where the charging ring is provided with a decorative member, an attraction magnet is arranged in the decorative member, and the attraction magnet and the cover closing magnets attract each other; and a top cover, being arranged on the decorative member.

The foldable wireless power bank provided by the present disclosure can not only perform wireless charging, but also is convenient to fold, such that carrying is convenient. Moreover, the foldable wireless power bank has relatively large damping after folding due to attraction of the magnets, such that the folded power bank will not be unfolded when a slight external force is applied, operation is simple, and practicability is strong.

### BRIEF DESCRIPTION OF DRAWINGS

FIG. 1 is a schematic diagram of an appearance of a foldable wireless power bank.

FIG. 2 is an exploded schematic diagram of a foldable wireless power bank.

FIG. 3 is a schematic diagram of a knurled shaft with larger and smaller edges of a foldable wireless power bank.

In the figures: 1—bottom cover, 2—key cap, 3—main board, 4—battery, 5—bottom housing, 6—cover closing magnet, 7—opening and closing mechanism, 8—charging mechanism, 9—wire, 71—top housing, 72—damping tube, 73—knurled shaft with larger and smaller edges, 74—top housing wire cover, 75—rotating shaft wire cover, 76—left locking pin, 77—right locking pin, 81—charging ring, 82—decorative member, 83—attraction magnet, and 84—top cover.

### DETAILED DESCRIPTION OF THE EMBODIMENTS

For making the objectives, technical solutions and advantages of the present disclosure clearer, the present disclosure will be further described in detail below in conjunction with the accompanying drawings and examples. It should be understood that the particular examples described herein are merely illustrative of the present disclosure and are not intended to limit the present disclosure.

Specific implementations of the present disclosure are described in detail below in conjunction with particular examples.

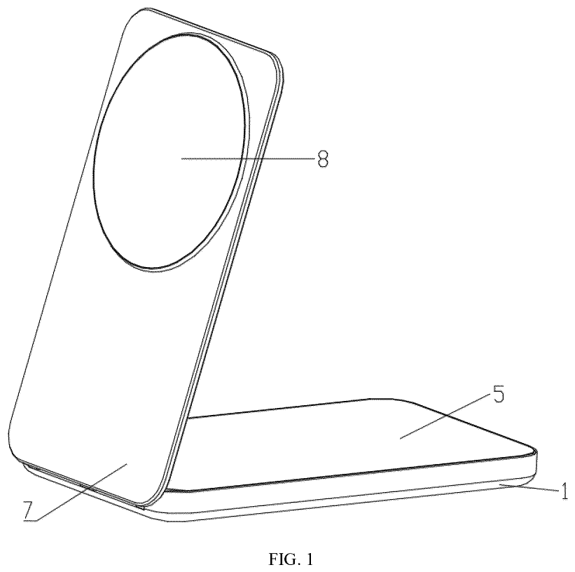

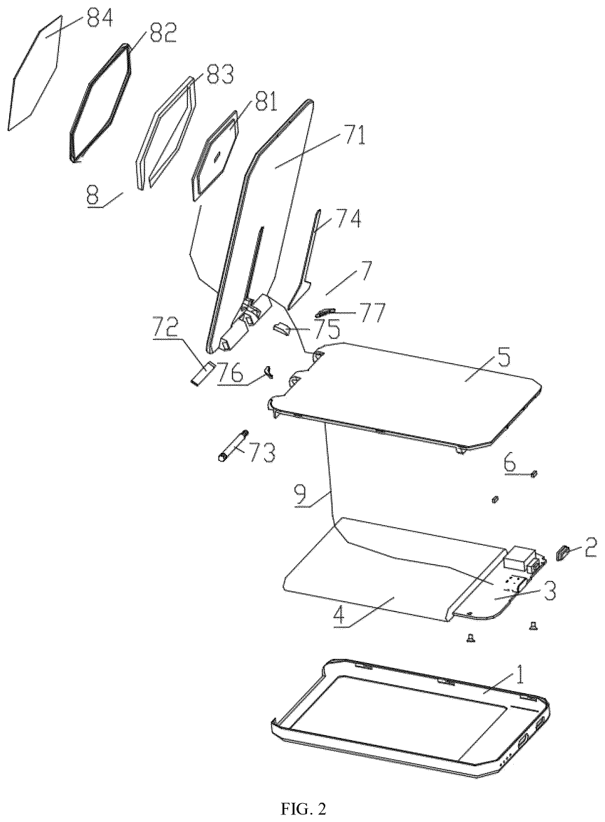

Referring to FIG. 1 and FIG. 2, the example of the present disclosure provides a foldable wireless power bank. The foldable wireless power bank includes:
a bottom cover 1, where the bottom cover 1 is provided with a key hole and concave buckles on side surfaces, and the key hole formed at the bottom cover 1 is fitted with a key cap 2; a main board 3, being fixedly mounted in the bottom cover 1 through screws and tightly attached to the key cap 2, where the main board 3 is connected to a battery 4 mounted in the bottom cover 1; a bottom housing 5, being provided with magnet grooves, convex buckles and shaft holes, where the convex buckles are arranged on side surfaces of the bottom housing 5, the convex buckles and the concave buckles match each other, the bottom housing 5 is clamped on the concave buckles arranged on the bottom cover 1 through the convex buckles, and cover closing magnets 6 are fixedly arranged in the magnet grooves formed at the bottom housing 5; and an opening and closing mechanism 7, being mounted at the shaft holes formed at the bottom housing 5, where the opening and closing mechanism 7 is capable of rotating on the bottom housing 5 so as to achieve opening and closing of the power bank, a charging mechanism 8 is mounted on the opening and closing mechanism 7, the charging mechanism 8 is connected to a wire 9, an end, farthest away from the charging mechanism 8, of the wire 9 is connected to the main board 3, and the wire 9 passes through the shaft holes.

When the foldable wireless power bank is used, firstly, the power bank can be unfolded through the opening and closing mechanism 7, and then, the key cap 2 can be pressed to connect a circuit between the battery 4 and the main board 3, such that the main board 3 can supply power to the charging mechanism 8 through the wire 9, and a device to be charged can be charged when being placed on the charging mechanism 8.

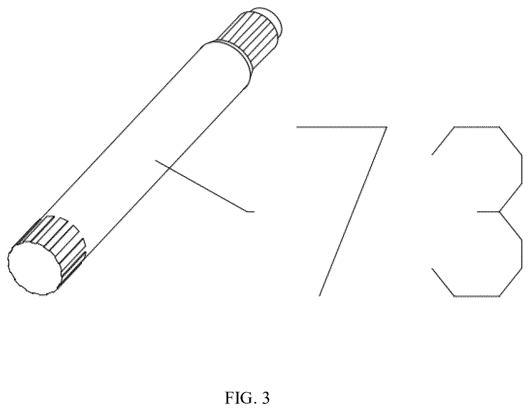

As shown in FIG. 2 and FIG. 3, as a preferred example of the present disclosure, the opening and closing mechanism 7 includes: a top housing 71, being provided with a fixing groove, where the top housing matches the shaft holes formed at the bottom housing 5, the charging mechanism 8 is mounted on the fixing groove formed at the top housing 71, a damping tube 72 is inserted into the top housing 71, a knurled shaft 73 with larger and smaller edges is inserted into the top housing 71 and the shaft holes formed at the bottom housing 5, and the knurled shaft 73 with larger and smaller edges passes through the damping tube 72; and a top housing wire cover 74, being mounted on the top housing 71, where a rotating shaft wire cover 75 is mounted on a rotating shaft of the top housing 71, and a left locking pin 76 and a right locking pin 77 used for blocking retreating space of the bottom housing 5 are clamped into a left side and a right side of the bottom housing 5 respectively.

When the power bank is unfolded, the top housing 71 is stirred, and the top housing 71 drives the damping tube 72 to rotate on the knurled shaft 73 with larger and smaller edges. Since a relatively large friction force exists between the damping tube 72 and the knurled shaft 73 with larger and smaller edges, the top housing 71 can be maintained at the position during unfolding, and the top housing wire cover 74 and the rotating shaft wire cover 75 can be mounted on the top housing 71, thereby improving beauty of the top housing 71 and facilitating passing of the wire 9 through the top housing 71. The left locking pin 76 and the right locking pin 77 may be clamped at the left side and the right side of the bottom housing 5 respectively, thereby blocking the retreating space of the bottom housing 5.

As shown in FIG. 2, as a preferred example of the present disclosure, the charging mechanism 8 includes: a charging ring 81, being mounted on the top housing 71 and connected to the wire 9, where the charging ring 81 is provided with a decorative member 82, an attraction magnet 83 is arranged in the decorative member 82, and the attraction magnet 83 and the cover closing magnets 6 attract each other; and a top cover 84, being arranged on the decorative member 82.

During charging, the device to be charged is placed on the top cover 84, the battery 4 can supply power to the charging ring 81 through the main board 3 and the wire 9, and the charging ring 81 can charge the device. When the power bank is folded, the attraction magnet 83 and the cover closing magnets 6 attract each other, such that no gap is formed after the power bank is folded, thus offsetting a resilience force after damping rotation.

The above-mentioned are merely preferred examples of the present disclosure, and are not intended to limit the present disclosure. Any modifications, equivalent replacements and improvements made within the spirit and principle of the present disclosure should fall within the protection scope of the present disclosure.

What is claimed is:

1. A foldable wireless power bank, comprising: a bottom cover, wherein the bottom cover is provided with a key hole and concave buckles on side surfaces, and the key hole formed at the bottom cover is fitted with a key cap;
a main board, being fixedly mounted in the bottom cover through screws and tightly attached to the key cap, wherein the main board is connected to a battery mounted in the bottom cover;
a bottom housing, being provided with magnet grooves, convex buckles and shaft holes, wherein the convex buckles are arranged on side surfaces of the bottom housing, the convex buckles and the concave buckles match each other, the bottom housing is clamped on the concave buckles arranged on the bottom cover through the convex buckles, and cover closing magnets are fixedly arranged in the magnet grooves formed at the bottom housing; and
an opening and closing mechanism, being mounted at the shaft holes formed at the bottom housing, wherein the opening and closing mechanism is capable of rotating on the bottom housing so as to achieve opening and closing of the power bank, a charging mechanism is mounted on the opening and closing mechanism, the charging mechanism is connected to a wire, an end, farthest away from the charging mechanism, of the wire is connected to the main board, and the wire passes through the shaft holes.

2. The foldable wireless power bank according to claim 1, wherein the opening and closing mechanism comprises:
a top housing, being provided with a fixing groove, wherein the top housing matches the shaft holes formed at the bottom housing, the charging mechanism is mounted on the fixing groove formed at the top housing, a damping tube is inserted into the top housing, a knurled shaft with larger and smaller edges is inserted into the top housing and the shaft holes formed at the bottom housing, and the knurled shaft with larger and smaller edges passes through the damping tube; and
a top housing wire cover, being mounted on the top housing, wherein a rotating shaft wire cover is mounted on a rotating shaft of the top housing, and a left locking pin and a right locking pin used for blocking retreating space of the bottom housing are clamped into a left side and a right side of the bottom housing respectively.

3. The foldable wireless power bank according to claim 2, wherein the charging mechanism comprises:
a charging ring, being mounted on the top housing and connected to the wire, wherein the charging ring is provided with a decorative member, an attraction magnet is arranged in the decorative member, and the attraction magnet and the cover closing magnets attract each other; and
a top cover, being arranged on the decorative member.
